(19) United States
(12) Patent Application Publication
(10) Pub. No.: US 2026/0082617 A1
(43) Pub. Date: Mar. 19, 2026

(54) LDMOS AND FABRICATING METHOD OF THE SAME

(71) Applicant: UNITED MICROELECTRONICS CORP., Hsin-Chu City (TW)

(72) Inventors: Hao-Ping Yan, Tainan City (TW); Ya-Hsin Huang, Tainan City (TW); Chin-Chia Kuo, Tainan City (TW); Wei-Hsuan Chang, Tainan City (TW); Ming-Hua Tsai, Tainan City (TW)

(73) Assignee: UNITED MICROELECTRONICS CORP., Hsin-Chu City (TW)

(21) Appl. No.: 18/916,740

(22) Filed: Oct. 16, 2024

(30) Foreign Application Priority Data
Sep. 18, 2024 (TW) 113135242

(51) Int. Cl. H01L 29/78; H01L 21/762; H01L 29/423; H01L 29/66

(52) U.S. Cl. CPC H10D 30/65; H10D 30/0285; H10D 64/514; H10W 10/0143; H10W 10/17

(57) ABSTRACT

An LDMOS includes a semiconductor substrate. The semiconductor substrate includes a fin structure and a planar substrate. The fin structure extends from the planar substrate. A gate electrode covers the planar substrate and the fin structure. A first gate dielectric layer is disposed between the gate electrode and the planar substrate. A second gate dielectric layer is between the gate electrode and the fin structure and between the gate electrode and the planar substrate. The first gate dielectric layer is connected to the second gate dielectric layer. A source is disposed in the fin structure at one side of the gate electrode and a drain is disposed in the planar structure at the other side of the gate electrode.

### BACKGROUND OF THE INVENTION

### 1. Field of the Invention

The present invention relates to a laterally diffused metal oxide semiconductor, and in particular to an LDMOS disposed on a fin structure and a planar substrate and a fabricating method of the same.

### 2. Description of the Prior Art

LDMOS has the characteristics of high breakdown voltage and compatibility with complementary metal oxide semiconductor technology in low voltage devices. Therefore, LDMOS is used in many applications, such as for mobile phones, ADSL drivers, LED displays, LCD display drivers, high power amplifiers for wireless base stations, and other power management. The main feature of the LDMOS is that it has a low doping concentration and a drift region with large area. These designs are used to alleviate the high voltage between the source and the drain, therefore, the LDMOS can has higher breakdown voltage.

As the complexity of wafers increases, there is a need for the LDMOS to react quickly, operate at low voltages but withstand high voltages.

### SUMMARY OF THE INVENTION

In view of this, the present invention provides an LDMOS disposed on both of a fin structure and a planar substrate. In this way, a thick gate dielectric can be formed on the planar substrate for withstand high voltage while the fin structure allows the LDMOS to be operated at low voltages.

According to a preferred embodiment of the present invention, an LDMOS includes a semiconductor substrate. The semiconductor substrate includes a fin structure and a planar substrate, wherein the fin structure extends from the planar substrate. A gate electrode covers the planar substrate and the fin structure. A first gate dielectric layer covers a first top surface of the planar substrate. The first gate dielectric layer is disposed between the gate electrode and the planar substrate. A second gate dielectric layer covers a second top surface of the fin structure and the first top surface of the planar substrate. The first gate dielectric layer is connected to the second gate dielectric layer. The second gate dielectric layer is between the gate electrode and the fin structure and between the gate electrode and the planar substrate. A source is disposed in the fin structure at one side of the gate electrode. A drain is disposed in the planar structure at the other side of the gate electrode.

According to another preferred embodiment of the present invention, a fabricating method of an LDMOS includes providing a semiconductor substrate. Later, the semiconductor substrate is patterned to form a fin structure and a planar substrate, wherein the fin structure extends from the planar substrate. Next, a first gate dielectric layer is formed to cover a first top surface of the planar substrate. After that, a second gate dielectric layer is formed to cover a second top surface of the fin structure and the first top surface of the planar substrate. Then, a gate electrode is formed to cover the first gate dielectric layer and the second gate dielectric layer. Finally, a source and a drain are formed, wherein the source is disposed in the fin structure at one side of the gate electrode, and the drain is disposed in the planar substrate at the other side of the gate electrode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 9 depict a fabricating method of an LDMOS according to a first preferred embodiment of the present invention, wherein:

FIG. 2 depicts a fabricating stage following FIG. 1;

FIG. 3 depicts a fabricating stage following FIG. 2;

FIG. 4 depicts a sectional view taking along a line AA′ in FIG. 3;

FIG. 5 depicts a fabricating stage following FIG. 4;

FIG. 6 depicts a top view of a fabricating stage following FIG. 5;

FIG. 7 depicts a sectional view taking along a line BB′ in FIG. 6;

FIG. 8 depicts a sectional view taking along a line CC′ in FIG. 6; and

FIG. 9 depicts sectional views taking along a line DD′ and a line EE′ in FIG. 6.

FIG. 10 to FIG. 15 depict a fabricating method of an LDMOS according to a second preferred embodiment of the present invention, wherein:

FIG. 11 depicts a fabricating stage following FIG. 10;

FIG. 12 depicts a sectional view taking along a line FF′ in FIG. 11;

FIG. 13 depicts a top view of a fabricating stage following FIG. 12;

FIG. 14 depicts a sectional view taking along a line GG′ in FIG. 13; and

FIG. 15 depicts a sectional view taking along a line HH′ in FIG. 13.

### DETAILED DESCRIPTION

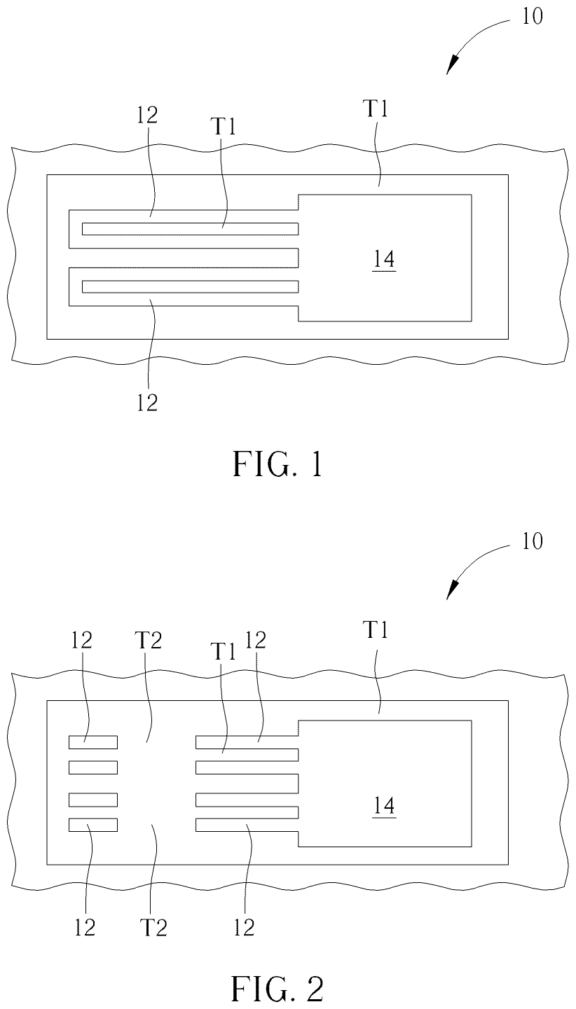

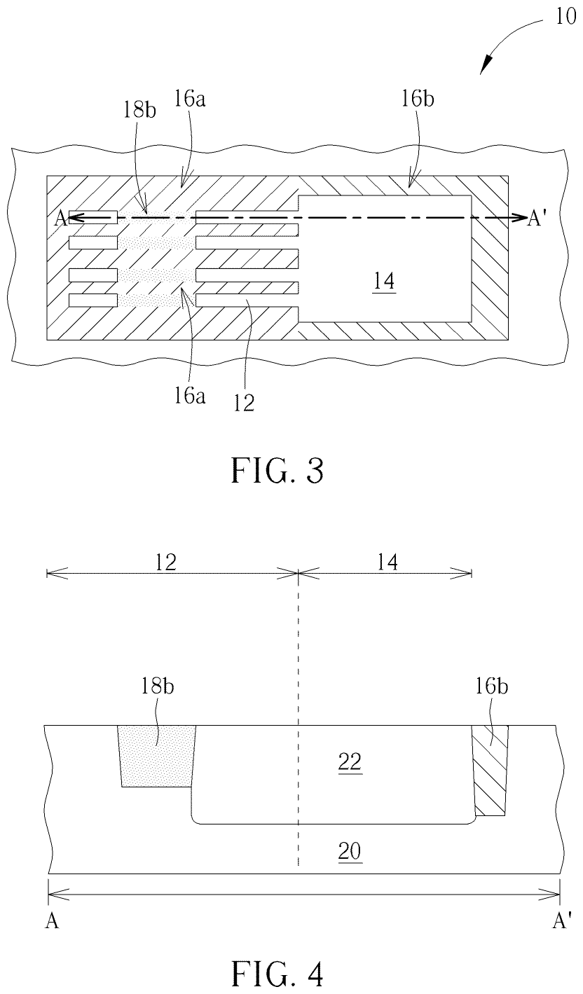

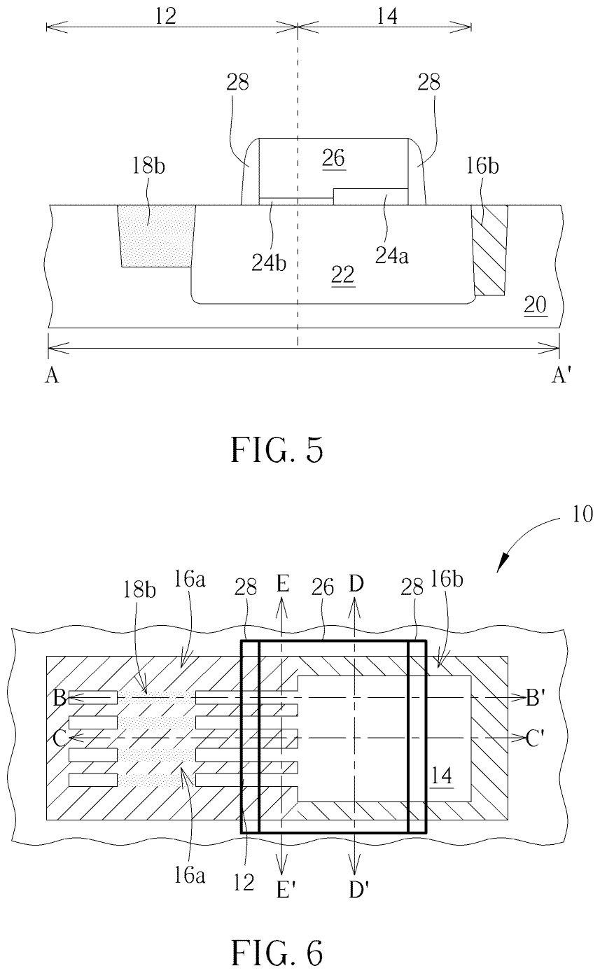

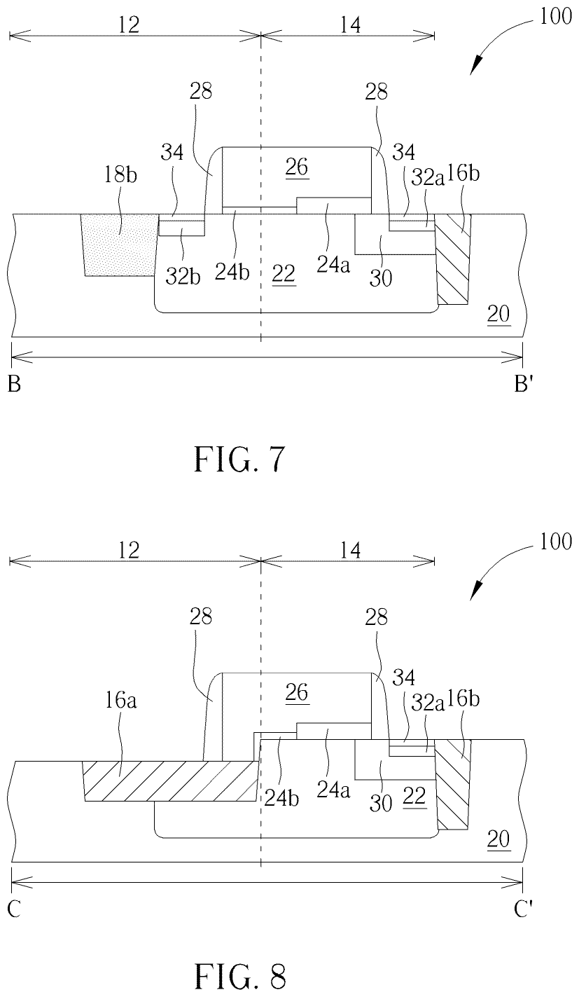

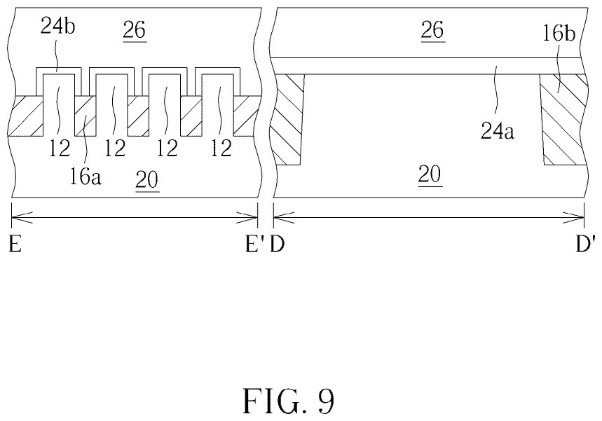

FIG. 1 to FIG. 9 depict a fabricating method of an LDMOS according to a first preferred embodiment of the present invention, wherein FIG. 4 depicts a sectional view taking along a line AA′ in FIG. 3. FIG. 6 depicts a top view of a fabricating stage following FIG. 5. FIG. 7 depicts a sectional view taking along a line BB′ in FIG. 6. FIG. 8 depicts a sectional view taking along a line CC′ in FIG. 6. FIG. 9 depicts sectional views taking along a line DD′ and a line EE′ in FIG. 6.

As shown in FIG. 1, a semiconductor substrate 10 is provided. The semiconductor substrate 10 includes a silicon substrate, a germanium substrate, a gallium arsenide substrate, a silicon germanium substrate, an indium phosphide substrate, a gallium nitride substrate, a silicon carbide substrate or a silicon-on-insulator substrate. Later, the semiconductor substrate 10 is patterned to form numerous of fin structures 12 and a planar substrate 14. Each of the fin structures 12 extends from the planar substrate 14. That is, each fin structure 12 is connected to the planar substrate 14. The fin structures 12 can be patterned by using a sidewall image transfer (SIT) process. Therefore, the ends of adjacent fin structures 12 are connected to each other. The process of patterning the semiconductor substrate 10 includes etching the semiconductor substrate 10 to form a trench T1 in the semiconductor substrate 10, and the trench T1 defines the positions of the fin structures 12 and the planar substrate 14. As shown in FIG. 2, a fin cut process is performed to separate the adjacent fin structures 12. Besides separating the adjacent fin structures 12, each fin structure 12 is divided into several segments. In details, each of the fin structures 12 are etched to form a trench T2 in each of the fin structures 12 in the fin cut process. In the following description, only one of the fin structures 12 will be described, however, each of the fin structures 12 goes through the same process.

As shown in FIG. 3 and FIG. 4, an insulating material layer is formed to fill the trench T1 and the trench T2 and cover the semiconductor substrate 10. The insulating material layer includes silicon oxide or silicon nitride. Next, the insulating material layer is planarized to remove the insulating material layer outside of the trench T1 and the trench T2. After that, only the insulating material layer around the fin structure 12 is etched back to make the fin structure 12 protrude from the insulating material layer. At this time, the insulating material layer surrounding the planar substrate 14 is defined as a second shallow trench isolation 16b. The insulating material layer between and surrounding the fin structure 12 is defined as a first shallow trench isolation 16a. The insulating material layer embedded in the fin structure 12 is defined as a second insulating structure 18b. Please refer to FIG. 4, the fin structure 12 and the planar substrate 14 between the second insulating structure 18b and the second shallow trench isolation 16b will serve as an active region to form an LDMOS in subsequent steps. Then, a deep doping region 20 and a doping region 22 are formed in the fin structures 12 and the planar substrate 14. The depth of doping region 22 is shallower than that of deep doping region 20.

As shown in FIG. 5, a first gate dielectric layer 24a is formed to cover the top surface of the planar substrate 14. Then, a second gate dielectric layer 24b is formed to cover the top surface of each fin structure 12 and the top surface of the planar substrate 14. In details, the first gate dielectric layer 24a is formed to blankly cover the top surface of the fin structure 12 and the top surface of the planar substrate 14. The first gate dielectric layer 24a is preferably formed by using a deposition process. Subsequently, the first gate dielectric layer 24a is patterned to make the first gate dielectric layer 24a disposed only on the planar substrate 14. Next, a second gate dielectric layer 24b is formed, and the second gate dielectric layer 24b covers the top surface of the fin structure 12 and the planar substrate 14 that is not covered by the first gate dielectric layer 24a. The second gate dielectric layer 24b is preferably formed by an oxidation process. Later, a gate electrode 26 is formed to blankly cover the fin structure 12 and the planar substrate 14. Next, the gate electrode 26 and the second gate dielectric layer 24b are simultaneously patterned by the same step to make the gate electrode 26 completely cover the first gate dielectric layer 24a and the second gate dielectric layer 24b. After that, two spacers 28 are formed at both sides of the gate electrode 26.

Please refer to FIG. 6, FIG. 7 and FIG. 8. For the sake of simplicity, some components are omitted in FIG. 6. For example, the doping well, the drift region, and the silicide layer are omitted. After the spacers 28 are formed, a drift region 30 is formed in the planar substrate 14 at one side of the gate electrode 26. Later, a drain 32a is formed in the drift region 30. The drain 32a is preferably a doping region. Next, a recess is formed by etching the fin structure 12 at the other side of gate electrode 26. Later, an epitaxial process is performed to form an epitaxial layer to fill the recess and to serve as a source 32b. Next, silicide layers 34 are respectively formed on the source 32b and the drain 32a. Now, an LDMOS 100 of the present invention is completed.

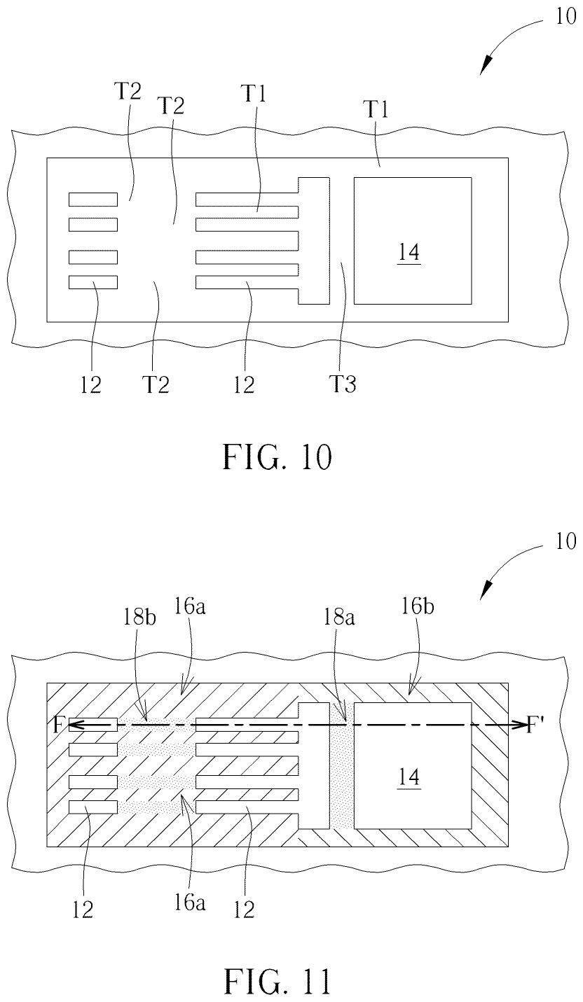

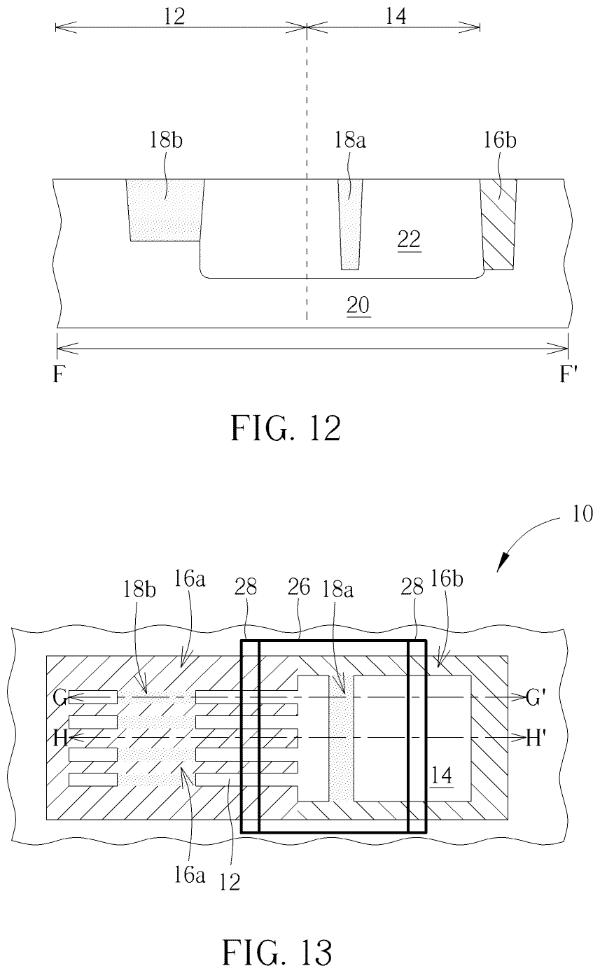

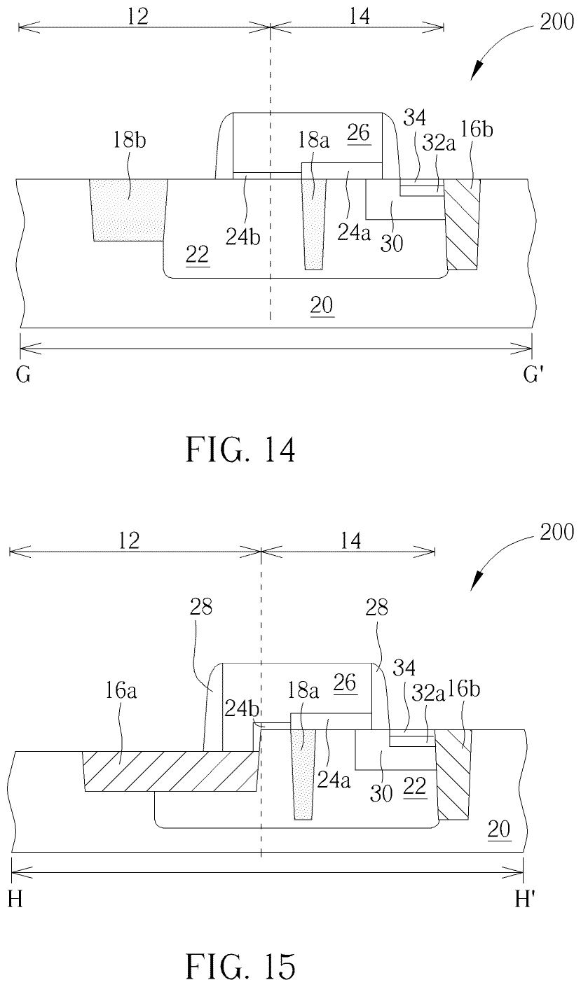

FIG. 10 to FIG. 15 depict a fabricating method of an LDMOS according to a second preferred embodiment of the present invention, wherein FIG. 12 depicts a sectional view taking along a line FF′ in FIG. 11. FIG. 13 depicts a top view of a fabricating stage following FIG. 12. FIG. 14 depicts a sectional view taking along a line GG′ in FIG. 13. FIG. 15 depicts a sectional view taking along a line HH′ in FIG. 13, wherein elements which are substantially the same as those in the first preferred embodiment are denoted by the same reference numerals; an accompanying explanation is therefore omitted.

The difference between the second preferred embodiment and the first preferred embodiment is that in the second preferred embodiment, a first insulating structure 18a is additionally provided. The first insulating structure 18a is embedded in the planar substrate 14, and below the gate electrode 26. As shown in FIG. 1, the semiconductor substrate 10 is patterned to form numerous fin structures 12 and a planar substrate 14. As shown in FIG. 10, when performing the fin cut process to separate the fin structures 12, a trench T3 is formed in the planar substrate 14 at the same time. Please refer to FIG. 11 and FIG. 12. An insulating material layer is formed to fill in the trench T1, the trench T2 and the trench T3. Similar to the process of the first preferred embodiment, the insulating material layer is planarized. Later, the insulating material layer around the fin structure 12 is etched back to form a first shallow trench isolation 16a, a second shallow trench isolation 16b, and a second insulating structure 18b. The insulating material layer filled in the trench T3 is defined as a first insulating structure 18a. The trench T3 for forming the first insulation structure 18a and the trench T2 for forming the second insulating structure 18b are both formed during the fin cut process. That is, the first insulating structure 18a and the second insulating structure 18b are formed by using the same process.

As shown in FIG. 13 to FIG. 15, similar to the process of the first preferred embodiment, the deep doping region 20, the doping region 22, the gate electrode 26, the first gate dielectric layer 24a, the second gate dielectric layer 24b, the spacers 28, the drift region 30, the drain 32b and the source 32b. Now, an LDMOS 200 is completed.

Please refer to FIG. 6 to FIG. 9. An LDMOS 100 includes a semiconductor substrate 10. The semiconductor substrate 10 includes a fin structure 12 and a planar substrate 14. The fin structure 12 extends from the planar substrate 14. A gate electrode 26 covers the planar substrate 14 and the fin structure 12. The gate electrode 14 includes polysilicon or metal. Two spacers 28 are disposed at two sides of the gate electrode 26. The spacers 28 include silicon nitride. A cap layer (not shown) can optionally be disposed on the gate electrode 26. A first gate dielectric layer 24a covers the top surface of the planar substrate 14. The first gate dielectric layer 24a is disposed between the gate electrode 26 and the planar substrate 14. A second gate dielectric layer 24b covers the top surface of the fin structure 12 and the top surface of the planar substrate 14. The first gate dielectric layer 24a and the second gate dielectric layer 24b are connected to each other. The second gate dielectric layer 24b is disposed between the gate electrode 26 and the fin structure 12 and between the gate electrode 26 and the planar substrate 14. The first gate dielectric layer 24a and the second gate dielectric layer 24b may respectively include oxide, silicon oxide, silicon oxynitride (SiON), silicon nitride (Si₃N₄), hafnium oxide (HfO), or a high dielectric constant (K>5) materials, or a combination of the above materials.

A source 32b is disposed in the fin structure 12 at one side of the gate electrode 26. A drain 32a is disposed in the planar substrate 14 at the other side of the gate electrode 26. A deep doping well 20 is embedded in the fin structure 12 and the planar substrate 14. A doping well 22 is embedded in the fin structure 12 and the planar substrate 14. The depth of the doping well 22 is shallower than that of the deep doping well 20. A drift region 30 is embedded in the planar substrate 14. The drain 32a is disposed in the drift region 30. The deep doping well 20, the doping well 22, the drift region 30, and the drain 32a are preferably formed by an ion implantation process. The conductive types of the deep doping well 20, the drift region 30, and the drain 32a are the same. The deep doping well 20, the drift region 30, and the drain 32a can be P-type or N-type. The doping well 22 is of another conductivity type, and the doping well 22 can be N-type or P-type. The source 32b is an epitaxial layer doped with N-type dopants or P-type dopants. For instance, the source 32b may be doped silicon germanium or doped silicon phosphide.

Moreover, two silicide layers 34 are respectively disposed on the source 32b and the drain 32a. The silicide layer 34 located on the drain 32a contacts the spacer 28 near to the drain 32a. The silicide layers 34 include nickel silicide (NiSi), platinum silicide (PtSi), titanium silicide (TiSi₂), and tungsten silicide (WSi₂). A second insulating structure 18b is embedded in the fin structure 12, and the second insulating structure 18b is adjacent to the source 32b. The second insulating structure 18b preferably contacts the source 32b. Furthermore, two first shallow trench isolations 16a are respectively disposed at two sides of the fin structure 12. The fin structure 12 protrudes from the first shallow trench isolation 16a. A second shallow trench isolation 16b is embedded in the semiconductor substrate 10, and surrounds the planar substrate 14. The top surface of the second shallow trench isolation 16b is higher than the top surface of the first shallow trench isolation 16a. The top surface of the second shallow trench isolation 16b, the top surface of the second insulating structure 18b, the top surface of the fin structure 12 and the top surface of the planar substrate 14 are aligned. The first shallow trench isolation 16a, the second shallow trench isolation 16b, and the second insulating structure 18b include silicon oxide or silicon nitride. The materials of the first shallow trench isolation 16a, the second shallow trench isolation 16b, and the second insulating structure 18b are the same.

As shown in FIG. 9, because the gate electrode 26 covers the planar substrate 14 and the fin structures 12, the bottom of the gate electrode 26 on planar substrate 14 is coplanar. However, the bottom of the gate electrode 26 on numerous fin structures 12 are with recesses. In other words, part of the bottom of the gate electrode 26 is coplanar, and part of the bottom of the gate electrode 26 is with recesses, which is not coplanar.

Please refer to FIG. 13 and FIG. 15, the difference between an LDMOS 200 and the LDMOS 100 is that that the LDMOS 200 has an additional first insulating structure 18a embedded in the planar substrate 14. The first insulating structure 18a is disposed below the gate electrode 26, and contacts the first gate dielectric layer 24a. The first insulating structure 18a and the second insulating structure 18b are made of the same material. Other elements in the LDMOS 200 are the same as those in the LDMOS 100 and the description is omitted.

The LDMOS of the present invention is arranged on both the fin structures and the planar substrate. Because part of the LDMOS semiconductor is disposed on the planar substrate, a thicker gate dielectric layer can be embedded in the planar substrate. Alternately, an insulating structure can be disposed in the planar substrate below the gate dielectric layer to increase the breakdown voltage of the LDMOS. In addition, because part of the LDMOS is disposed in the fin structure, the LDMOS can have a lower turn-on voltage and a faster reacting speed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A laterally diffused metal oxide semiconductor (LDMOS), comprising:
a semiconductor substrate comprising a fin structure and a planar substrate, wherein the fin structure extends from the planar substrate;
a gate electrode covering the planar substrate and the fin structure;
a first gate dielectric layer covering a first top surface of the planar substrate, wherein the first gate dielectric layer is disposed between the gate electrode and the planar substrate;
a second gate dielectric layer covering a second top surface of the fin structure and the first top surface of the planar substrate, wherein the first gate dielectric layer is connected to the second gate dielectric layer, the second gate dielectric layer is between the gate electrode and the fin structure and between the gate electrode and the planar substrate;
a source is disposed in the fin structure at one side of the gate electrode; and
a drain is disposed in the planar structure at the other side of the gate electrode.

2. The LDMOS of claim 1, wherein a thickness of the first gate dielectric layer is greater than a thickness of the second gate dielectric layer.

3. The LDMOS of claim 1, further comprising a first insulating structure embedded in the planar substrate, wherein the first insulating structure is disposed below the gate electrode, and the first insulating structure contacts the first gate dielectric layer.

4. The LDMOS of claim 1, further comprising a second insulating structure embedded in the fin structure, wherein the second insulating structure is adjacent to the source.

5. The LDMOS of claim 1, further comprising
two spacers dipsoed at two sides of the gate electrode; and
two silicide layers respectively disposed on the source and the drain, wherein
the silicide layer dipsoed on the drain contacts one of the two spacers.

6. The LDMOS of claim 1, further comprising:
two first shallow trench isolations respectively disposed at two sides of the fin structure, wherein the fin structure protrudes from the two first shallow trench isolations; and
a second shallow trench isolation embedded in the semiconductor substrate, wherein the second shallow trench isolation surrounds the planar substrate.

7. The LDMOS of claim 6, wherein a top surface of the second shallow trench isolation is higher than a top surface of each of the two first shallow trench isolations.

8. The LDMOS of claim 1, wherein the first gate dielectric layer is only disposed on the planar substrate.

9. A fabricating method of a laterally diffused metal oxide semiconductor (LDMOS), comprising:
providing a semiconductor substrate;
patterning the semiconductor substrate to form a fin structure and a planar substrate, wherein the fin structure extends from the planar substrate;
forming a first gate dielectric layer covering a first top surface of the planar substrate;
forming a second gate dielectric layer covering a second top surface of the fin structure and the first top surface of the planar substrate;
forming a gate electrode covering the first gate dielectric layer and the second gate dielectric layer; and
forming a source and a drain, wherein the source is disposed in the fin structure at one side of the gate electrode, and the drain is disposed in the planar substrate at the other side of the gate electrode.

10. The fabricating method of an LDMOS of claim 9, wherein a thickness of the first gate dielectric layer is greater than a thickness of the second gate dielectric layer.

11. The fabricating method of an LDMOS of claim 9, further comprising forming a first insulating structure embedded in the planar substrate, wherein the first insulating structure is disposed below the gate electrode, and the first insulating structure contacts the first gate dielectric layer.

12. The fabricating method of an LDMOS of claim 11, further comprising while forming the first insulating structure, forming a second insulating structure embedded in the fin structure, wherein the second insulating structure is adjacent to the source.

13. The fabricating method of an LDMOS of claim 9, further comprising:
after forming the gate electrode, forming two spacers dipsoed at two sides of the gate electrode; and
after forming the source and the drain, forming two silicide layers respectively disposed on the source and the drain, wherein the silicide layer dipsoed on the drain contacts one of the two spacers.

14. The fabricating method of an LDMOS of claim 9, further comprising:
after forming the fin structure and the planar substrate, forming two first shallow trench isolations, and a second shallow trench isolation, wherien the two first shallow trench isolations are respectively disposed at two sides of the fin structure, the second shallow trench isolation is embedded in the semiconductor substrate, and the second shallow trench isolation surrounds the planar substrate.

15. The fabricating method of an LDMOS of claim 14, wherein a top surface of the second shallow trench isolation is higher than a top surface of each of the two first shallow trench isolations.

16. The fabricating method of an LDMOS of claim 9, wherein the first gate dielectric layer is only disposed on the planar substrate.
